(19) United States
(12) Patent Application Publication
(10) Pub. No.: US 2026/0214849 A1
(43) Pub. Date: Jul. 23, 2026

(54) COOLING DEVICE

(71) Applicant: Shenzhen Envicool Technology Co., Ltd., Shenzhen, Guangdong (CN)

(72) Inventors: Lichuan WEI, Shenzhen, Guangdong (CN); Xiaodong ZHANG, Shenzhen, Guangdong (CN); John C. CHAI, Shenzhen, Guangdong (CN); Yugang ZHAO, Shenzhen, Guangdong (CN); Wei TONG, Shenzhen, Guangdong (CN)

(73) Assignee: Shenzhen Envicool Technology Co., Ltd., Shenzhen, Guangdong (CN)

(21) Appl. No.: 18/863,272

(22) PCT Filed: Mar. 7, 2023
(86) PCT No.: PCT/CN2023/080033

§ 371 Date: Nov. 5, 2024

(30) Foreign Application Priority Data
May 6, 2022 (CN) 202210486557.5

(51) Int. Cl. H05K 7/20

(52) U.S. Cl. CPC H05K 7/20327

(57) ABSTRACT

Disclosed is a cooling device including a tank, a foaming device and a circulating device. A cooling cavity is formed in the tank. Cooling liquid is contained in the cooling cavity to cool a heat generating object. A part of the structure of the foaming device is immersed in the cooling liquid and can generate bubbles. The bubbles can rise in the cooling liquid until closely fitting the surface to be cooled of the heat generating object. The circulating device is connected to the tank and configured to collect and condense vaporized cooling liquid and then redeliver into the cooling cavity. By arranging the foaming device, the bubble group is generated to flush the surface of the heat generating element, so as to substitute the vaporization nucleation, evaporation of liquid near the heat generating element is accelerated.

### TECHNICAL FIELD

The present disclosure relates to the technical field of enhanced heat transfer, and in particular, to a cooling device.

### BACKGROUND

In the technical fields of chip cooling, communication equipment heat dissipation, battery heat management, data center heat dissipation and the like, due to the rapid development of electronic devices and integrated circuit technology, the problems of narrow physical size and increasing total power density become more and more severe, and the heat flow density of subsequent electronic devices is also continuously increasing. High temperature caused by the high heat flow density may adversely affects the performance of the electronic devices, and may even burn the whole device in severe cases.

In the related art, an immersion type liquid evaporation phase change cooling technology is used for cooling a heat generating element in an electronic device. A large amount of latent heat can be absorbed during the liquid evaporation phase change process, so as to achieve higher cooling capacity, which is more beneficial to the heat transfer of high heat flow density within a small space. However, in the related art, the cooling capacity of the immersion liquid evaporation phase change cooling technology needs to be improved. The capacity for high intensity heat dissipation is insufficient.

### SUMMARY

Based on this, it is necessary to provide a cooling device for improving the cooling heat exchange capacity.

A cooling device includes: a tank, a foaming device and a circulation device.

The tank includes a sealable cooling cavity for containing cooling liquid therein. The heat generating object can be arranged in the cooling cavity for cooling by the cooling liquid.

A partial structure of the foaming device is immersed in the cooling liquid, and can generate bubbles inside the cooling liquid, and the bubbles can rise inside the cooling liquid until closely fitting a surface to be cooled of the heat generating object.

The circulation device is connected to the tank and configured to collect and condense the vaporized cooling liquid and then redeliver the vaporized cooling liquid into the cooling cavity.

In some embodiments of the cooling device, the foaming device includes an air pump for providing non-condensable gas and a bubble generator connected to the air pump, and the bubble generator is provided in the cooling cavity and below a position where the heat generating object is located when the heat generating object is being cooled, so that the gas generated by the air pump can rise and impact the heat generating object after discharged through the bubble generator.

In some embodiments of the cooling device, the bubble generator comprises sintered metal or ceramic-based bubble stone, or a sprayer with one or more holes, and the bubble generator is capable of generating more than five bubbles per cubic millimeter.

In some embodiments of the cooling device, the cooling device further includes a detection feedback device. The detection feedback device includes a temperature detector configured to detect a surface temperature of the heat generating object and a feedback controller in signal connection with the temperature detector. The feedback controller is in signal connection with the foaming device and is capable of controlling a foaming quantity of the foaming device according to the temperature detected by the temperature detector.

In some embodiments of the cooling device, the circulation device includes a steam outlet, a gas-liquid separator and a backflow inlet. One end of the steam outlet and one end of the backflow inlet are introduced into the cooling cavity, the steam outlet and the backflow inlet are both communicated with the gas-liquid separator through pipelines, the backflow inlet is arranged on or below a liquid level of the cooling liquid in the cooling cavity, and a first one-way valve is provided between the gas-liquid separator and the backflow inlet.

In some embodiments of the cooling device, a condenser in which the cooling water is communicated is further provided on a pipeline of the steam outlet for communicating with the gas-liquid separator, and the condenser is configured to cool and liquefy the vaporized cooling liquid.

In some embodiments of the cooling device, the gas-liquid separator is further provided with a pressure regulating device for regulating an internal pressure thereof.

In some embodiments of the cooling device, the pressure regulating device includes a second one-way valve connected to the gas-liquid separator and a pressure regulator connected to the second one-way valve.

In some embodiments of the cooling device, the cooling liquid is selected from water, an organic solvent or a mixed liquid according to the working temperature of the heat generating object.

In some embodiments of the cooling device, a side wall of the tank is provided with an observation plate for observing an internal condition of the tank, and the observation plate is made of transparent quartz, acrylic or PC material.

The embodiments of the present disclosure have the following beneficial effects:

It can be seen from the above that, by arranging the foaming device capable of generating the bubble group in the cooling liquid body, the bubble group is used to flush the surface of the heat generating element, so that the bubbles can substitute the vaporization nucleation, the evaporation of the liquid close to the heat generating element is accelerated, and the degree of the surface superheat of the heat generating element can be reduced. In this case, when under the working condition with a low heat flux density, the heat generating element can present a pseudo-boiling phenomenon with the degree of the surface superheat less than zero, and when under the working condition with a high heat flux density, the bubble group can assist the separation of the vaporization nucleation from the surface of the heat generating element, improve the upper limit of the heat exchange capacity, prevent or delay the film boiling, and improve the critical heat flux density. As a result, the equipment phase change heat cooling capacity is improved, and the high demand of heat dissipation can be satisfied. Moreover, the cooling device according to the embodiments of the present disclosure has a simple structure and a more compact size, so as to reduce the filling of working liquid and the cost.

### BRIEF DESCRIPTION OF DRAWINGS

In order to better illustrate the embodiments of the present disclosure or the technical solutions in the related art, the drawings, which are intended to be used in the description of the embodiments or the related art, are briefly described as below. It is appreciated that the drawings in the following descriptions are merely some embodiments of the present disclosure, and other drawings may be obtained by those skilled in the art according to these drawings without paying any creative efforts.

In the figures,

FIG. 1 shows a schematic structural diagram of a cooling device according to an embodiment of the present disclosure; and

FIG. 2 shows a schematic structural diagram of a tank of a cooling device according to an embodiment of the present disclosure.

### DETAILED DESCRIPTION OF EMBODIMENTS

To facilitate understanding of the present disclosure, the present disclosure will be described below with reference to the drawings. It is appreciated that, the described embodiments are only some of the embodiments of the present disclosure, rather than all of them. On the basis of the present disclosure, all other embodiments obtained by those skilled in the art without creative efforts shall fall into the protection scope of the present disclosure.

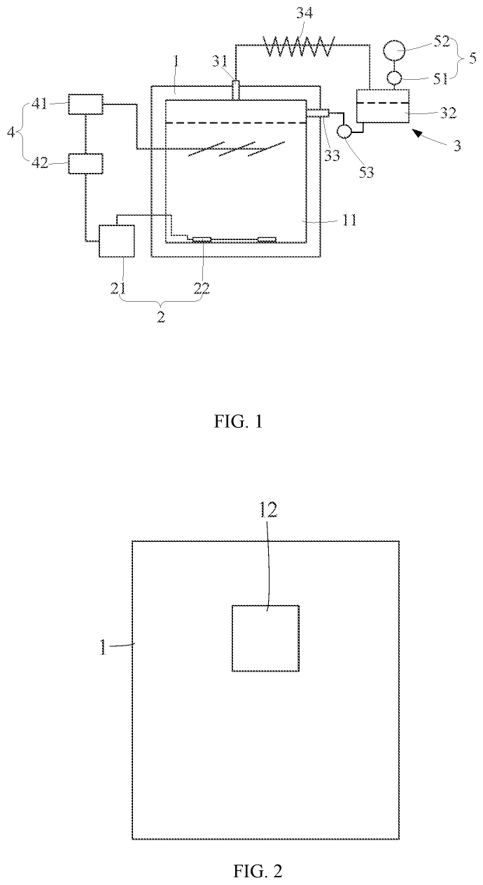

Embodiments of the present disclosure provide a cooling device for cooling a heat generating object, and in particular, for cooling a heat generating element of an electronic device. In an embodiment, as shown in FIG. 1, the cooling device includes a tank 1, a foaming device 2 and a circulation device 3. The tank 1 has a sealable cooling cavity 11 for containing cooling liquid, and the dotted line in the figure indicates a liquid level of the cooling liquid. The cooling cavity 11 needs to be sealed enough to prevent liquid leakage and pressure leakage. The heat generating element can be placed in the cooling cavity 11 with the cooling liquid for cooling by evaporation and heat absorption of the cooling liquid. It should be noted that the cooling liquid may be water, an organic solvent or a mixed liquid. In actual application, a liquid having a proper boiling point and being non-combustible may be selected according to the working temperature of the heat generating element. For example, an FC-72 fluorinated liquid or the like may be adopted.

It is worth noted that the material for manufacturing the tank 1 can be selected according to specific application objects. The tank 1 is generally manufactured from metal materials or polymer plates. With reference to FIG. 2, in order to clearly observe the internal condition of the tank 1, an observation plate 12 for observing the internal condition of the tank 1 may also be provided at a suitable position on the side wall of the tank 1. The observation plate 12 is embedded in the side wall of the tank 1 or adhered to the side wall of the tank 1. The observation plate 12 may be made of transparent quartz, acrylic or PC material.

The foaming device 2 has a foaming part. The foaming part can be provided in the cooling cavity 11 with the cooling liquid, and the foaming part can generate bubbles for impacting the surface to be cooled (hereinafter referred to as “cooling surface”) of the heat generating element inside the cooling liquid. This requires that the portion of the foaming part is below the heat generating element in the cooling cavity 11, so that the bubbles generated by the foaming portion can fit the cooling surface during the rising process in the cooling liquid. It is worth noted that the heat generating element needs to be immersed in the cooling liquid during cooling, and in order that the bubbles generated by the foaming part can be easily separated from the cooling surface to take away the temperature of the cooling surface when fitting to the cooling surface, in an embodiment of the present disclosure, the cooling surface (the surface which the bubbles fit) of the heat generating element needs to be inclined at a certain angle with respect to a plane perpendicular to the rising direction of the bubbles, which is not less than 15°. Generally, the tank 1 is placed on a horizontal plane, and a rising direction of the air bubbles in the cooling liquid is perpendicular to the horizontal plane. Accordingly,, the cooling surface needs to be inclined at an angle not less than 15° with respect to the horizontal plane. The cooling surface is inclined by a certain angle, so that bubbles on the cooling surface can roll away along the cooling surface, and thus heat dissipation can be normally carried out.

The circulating device 3 is arranged on the tank 1, and the circulating device 3 is used for recycling the cooling liquid, which can collect and condense the vaporized cooling liquid and then redeliver the vaporized cooling liquid into the cooling cavity 11.

The cooling apparatus according to embodiments of the present disclosure can be applied to cooling of devices in various fields, such as chip cooling, communication device heat dissipation, battery heat management, and data center heat dissipation. In an embodiment, the cooling of the heat generating element of the electronic device is illustrated as an example. In the related art, an immersion liquid evaporation phase change cooling technology is used to cool the heat generating element. That is, the heat generating element is immersed in the cooling liquid, and the heat of the heat generating element is taken away by heat absorption of the evaporation of the cooling liquid. Due to the fact that a large amount of latent heat is absorbed in the evaporation phase change process, the cooling capacity of a liquid cooling plate or submerged single-phase liquid cooling in the related art is much higher than that of other traditional technologies, which is more favorable to the heat transfer of high heat flow density in a small space. In addition, the heat generating element is directly in contact with the cooling liquid, so as to reduce the thermal resistance caused by the addition of the heat-conducting material (such as heat-conducting paste and heat-conducting sheet) in the indirect cooling system. In the evaporative phase change system, the cooling liquid realizes cooling heat exchange due to pool boiling, so as to avoid the extra power generated by devices such as a pump when the cooling liquid in the submerged single-phase liquid cooling system flows circularly, and thereby reducing the energy consumption of the system.

The main influencing factors affecting the evaporation efficiency of the cooling liquid in the evaporative phase change system include: (1) the degree of the surface superheat of the heat generating element (i.e., the difference value of the surface temperature higher than the boiling point of the cooling liquid): the surface of the heat generating element needs to reach a certain degree of superheat to initiate the excitation on the surface to form a vaporization nucleation, the vaporization nucleation herein refers to bubbles generated by that the heat on the heat generating element heats the cooling liquid near the heat generating element, and the lower the ideal degree of superheat on the surface of the heat generating element is, the better, so that the heat generating element can be protected from causing excessive temperature; (2) the separation frequency of the vaporization nucleation and the average particle size of the separated bubbles: the main way to use the boiling of the cooling liquid for cooling (referred to as “boiling phase change cooling”) is that the surface of the heat generating element starts to generate the vaporization nucleation and the vaporization nucleation is separated from the surface of the heat generating element, the higher the separation frequency of the vaporization nucleation is, the smaller the average particle size of the separated bubbles will be, the higher the amount of effective vaporization nucleation and the phase interface density (i.e., the contact area between the vaporization nucleation and the surface of the heat generating element) are, the higher the heat exchange efficiency of the evaporation phase change is, the more the heat taken away from the heat generating element is, and the better the cooling effect will be; and (3) the critical heat flow density: the surface temperature of the heat generating element is so high that it has exceeded the critical heat flow density, the boiling mode may be converted, a continuous gas film is formed on the surface of the heat generating element to cause film boiling, heat exchange between the surface of the heat generating element and the liquid is prevented, the temperature of the heat generating element is sharply increased, and boiling phase change cooling is facilitated by the higher critical heat flow density. It is the key of developing a new generation of boiling phase change cooling technology how to rapidly generate vaporization nucleation to trigger boiling under the low degree of superheat on the surface of the heat generating element, improve the separation frequency of the vaporization nucleation and reduce the average particle size of the separated bubbles, so as to increase the density of effective vaporization nucleation and the phase interface, improve the critical heat flow density and prevent film boiling. The existing methods for promoting the generation of the vaporization nucleation, increasing the density of the phase interface and preventing film boiling are electrolytic methods, surface modification methods and the like, which have the disadvantages of poor enhancement effect and persistence, complicated structure and expensive cost, and thus are difficult to be commercially available on a large scale.

On the basis of traditional phase change liquid cooling of the cooling device according to an embodiment of the present disclosure, the foaming device 2 which can generate bubble groups is arranged. The bubble groups are used to flush the surface of the heat generating element, and the bubble group can replace the vaporization nucleation, so that the effective vaporization nucleation and the phase interface working density of the cooling surface are greatly increased, the vaporization rate of the cooling liquid is greatly increased, and the heat exchange efficiency is therefore increased. In an embodiment, when the heat generating element operates at a low power and the surface temperature is lower than the boiling point of the cooling liquid, after the bubble groups generated by the foaming device 2 impact the surface to be cooled of the heat generating element, the vaporization nucleation generated when the cooling liquid boils is replaced, so that the working liquid near the surface of the heat generating element is in a pseudo-boiling state. After the bubbles hit the surface of the heat generating element, liquid near the bubbles vaporizes and absorbs a large amount of heat of the heat generating element, vapor generated after vaporization is stored in the bubbles, evaporation of cooling liquid near the heat generating element is accelerated, the phase change heat cooling capacity is improved, the bubbles can be separated from the heat generating element along the surface of the heat generating element, the heat of the heat generating element is taken away, and the degree of the surface superheat required by initial boiling is reduced.

When the heat generating element operates at a high power and the surface temperature is higher than the boiling point of the cooling liquid, the cooling liquid generates a vaporization nucleation on the surface of the heat generating element due to the high temperature of the heat generating element, and the bubble group generated by the foaming device 2 flushes the surface of the heat generating element, and is combined with the vaporization nucleation generated by the cooling liquid on the surface of the heat generating element due to the temperature higher than the boiling point and then is separated from the cooling surface, so that the vaporization nucleation can be assisted to be separated from the surface of the heat generating element, and the separation frequency of the vaporization nucleation is improved. Due to the assistance of the bubble group, the time for separating the vaporization nucleation from the heat generating element is advanced, so that the average particle size during separation is reduced, and the densities of the effective vaporization nucleation and the phase interface are increased. As a result, film boiling is prevented or delayed, the critical heat flow density is improved, liquid evaporation near the heat generating element is accelerated, the vaporization latent heat absorbs a large amount of heat to reduce the surface temperature of the heat generating element, and thus the high requirement of heat dissipation is satisfied.

It can be seen from the above that, by arranging the foaming device 2 capable of generating the bubble groups in the cooling liquid, the bubble group is used to flush the surface of the heat generating element, so that the bubbles can replace the vaporization nucleation, the evaporation of the liquid near the heat generating element is accelerated, and the degree of the surface superheat of the heat generating element can be reduced. As a result, under the working condition with a low heat flux density, the heat generating element can present a pseudo-boiling phenomenon with the degree of the surface superheat less than zero. Under the working condition with a high heat flux density, the bubble group can assist the separation of the vaporization nucleation on the surface of the heat generating element, the upper limit of the heat exchange capacity is improved, the film boiling is prevented or delayed, the critical heat flux density is improved, so that the phase change heat cooling capacity of the equipment is improved, and the high requirement of heat dissipation is satisfied. Moreover, the cooling device according to the embodiments of the present disclosure is simple in structure and more compact in size, the filling of working liquid is reduced, and thus the cost is reduced.

In an embodiment, as shown in FIG. 1, the foaming device 2 includes an air pump 21 and a bubble generator 22 connected to the air pump 21. The air pump 21 is connected to the bubble generator 22 through an air delivery pipe to supply gas to the bubble generator 22. That is, the bubble generator 22 is the foaming part of the foaming device 2 and can discharge the gas. The gas provided by the air pump 21 is a non-condensable gas. For example, the air pump 21 may provide a non-condensable gas such as air, nitrogen or argon, and the flow rate of the gas may be controlled by an air valve inside the air pump 21, or controlled by adding a flow rate regulating valve to an air delivery pipe. The bubble generator 22 is provided in the cooling cavity 11 and below the position where the heat generating object is located during cooling, and may be located directly below or at a certain angle, as long as the generated bubbles can reach the surface of the heat generating object, so that the gas generated by the air pump 21 can rise and impact the heat generating object after being discharged through the bubble generator 22.

It should be noted that the bubble generator 22 is a sintered metal or ceramic-based bubble stone, or a sprayer having a plurality of holes. No matter whether the bubble generator 22 is a bubble stone or a sprayer, the holes thereof for discharging air are microporous structures, and the pore diameters of these microporous structures are 1-50 μm. By controlling the air outlet flow of the air pump 21, the aperture of the bubbles can be controlled, so that the particle size is 0.1-200 μm when the bubbles contact the cooling surface of the heat generating element, and the density of the bubbles can be controlled to generate more than five bubbles per cubic millimeter. By arranging the aperture of the micro-pores, a large amount of microbubble groups can be generated in the cooling liquid, so that the separation frequency of the vaporization nucleation is improved, the average particle size of the separated bubbles is reduced, the effective phase interface density is increased, the critical heat flow density is improved, and thus film boiling is prevented or delayed.

In an embodiment, referring to FIG. 1, the cooling device further includes a detection feedback device 4. The detection feedback device 4 includes a temperature detector 41 for detecting a surface temperature of the heat generating object and a feedback controller 42 in signal connection with the temperature detector 41. A detection end of the temperature detector 41 can extend into the cooling cavity 11 to be connected to the heat generating element, so as to detect a temperature of a surface of the heat generating element. The feedback controller 42 is also in signal connection with the foaming device 2, and, in an embodiment, can be connected with the air pump 21, which can adjust the power of the air pump 21 or the flow rate of the gas according to the temperature range detected by the temperature detector 41, so as to achieve optimal matching between the amount of bubbles and the surface temperature of the heat generating element, and thus to reduce unnecessary consumption.

In an embodiment, referring to FIG. 1, the circulation device 3 includes a steam outlet 31 with one end introduced into the cooling cavity 11, a gas-liquid separator 32 and a backflow inlet 33 with one end introduced into the cooling cavity 11, and the steam outlet 31 and the backflow inlet 33 are both communicated with the gas-liquid separator 32 through pipelines. The cooling liquid heated and vaporized in the cooling cavity 11 can be output from the vapor outlet 31 and enter into the gas-liquid separator 32 along the pipelines, and the vaporized cooling liquid can be re-liquefied and stored in the gas-liquid separator 32 during the delivering process, and then enter the cooling cavity 11 again through the backflow inlet 33, thereby realizing the recycling of the cooling liquid and reducing the cost. It is worth noted that the backflow inlet 33 may be located on the liquid level of the cooling liquid in the cooling cavity 11, or may be located below the liquid level of the cooling liquid, and a first one-way valve 53 is provided between the gas-liquid separator 32 and the backflow inlet 33, and can prevent the liquid or vaporized cooling liquid in the cooling cavity 11 from flowing from the backflow inlet 33 to the gas-liquid separator 32.

It should be noted that a condenser 34 in which cooling water is communicated is provided on the outer wall of the pipeline, along the path of the pipeline, of the steam outlet 31 for communicating with the gas-liquid separator 32. When the vaporized cooling liquid flows in the pipeline, the cooling water in the condenser 34 can be liquefied more completely.

It is worth noted that the gas-liquid separator 32 is further provided with a pressure regulating device 5 for regulating the internal pressure thereof, the pressure regulating device 5 includes a one-way valve 51 connected to the gas-liquid separator 32 and a pressure regulator 52 connected to the one-way valve 51. The one-way valve 51 can prevent the air pressure in the gas-liquid separator 32 from leaking, and the pressure regulator 52 is configured to regulate the pressure in the gas-liquid separator 32. The pressure in the cooling cavity 11 may also be controlled by the one-way valve 51 and the pressure regulator 52. Generally, the pressure in the cooling cavity 11 may be set to be slightly higher than the ambient pressure, or may be flexibly adjusted according to working requirements.

The various technical features of the above embodiments can be combined in any way. In order to make the description concise, not all possible combinations of the technical features in the foregoing embodiments are described. However, as long as there is no contradiction between the combinations of the technical features, it should be considered as belonging to the scope of the specification.

The above embodiments merely express several embodiments of the present disclosure, and the description thereof is more specific and detailed, but should not be construed as limiting the scope of the present disclosure. It can be understood that those skilled in the art may make several modifications and improvements without departing from the concept of the present disclosure, which fall within the scope of the present disclosure. Therefore, the scope of the present disclosure shall be defined by the appended claims.

What is claimed is:

1. A cooling device for cooling a heat generating object, comprising:
a tank comprising a sealable cooling cavity for containing a cooling liquid inside the tank, wherein the heat generating object is capable of being arranged in the cooling cavity for cooling by the cooling liquid;
a foaming device, wherein a partial structure of the foaming device is immersed in the cooling liquid and is capable of generating bubbles inside the cooling liquid, and the bubbles are capable of rising inside the cooling liquid until fitting a surface to be cooled of the heat generating object; and
a circulation device connected to the tank and configured to collect and condense vaporized cooling liquid and redeliver the vaporized cooling liquid into the cooling cavity.

2. The cooling device according to claim 1, wherein the foaming device comprises an air pump for providing non-condensable gas and a bubble generator connected to the air pump, and the bubble generator is arranged in the cooling cavity and below a position of the heat generating object when the heat generating object is being cooled, so that the gas generated by the air pump is capable of rising and impacting the heat generating object after discharged through the bubble generator.

3. The cooling device according to claim 2, wherein the bubble generator comprises sintered metal or ceramic-based bubble stone, or a sprayer having a plurality of holes, and the bubble generator is capable of generating more than five bubbles per cubic millimeter.

4. The cooling device according to claim 1, further comprising a detection feedback device, wherein the detection feedback device comprises a temperature detector for detecting a surface temperature of the heat generating object and a feedback controller in signal connection with the temperature detector, and the feedback controller is in signal connection with the foaming device and is capable of controlling a foaming amount of the foaming device according to the temperature detected by the temperature detector.

5. The cooling device according to claim 1, wherein the circulation device comprises a steam outlet, a gas-liquid separator and a backflow inlet, one end of the steam outlet and one end of the backflow inlet are introduced into the cooling cavity, the steam outlet and the backflow inlet are both communicated with the gas-liquid separator through pipelines, the backflow inlet is provided above or below a liquid level of the cooling liquid in the cooling cavity, and a first one-way valve is provided between the gas-liquid separator and the backflow inlet.

6. The cooling device according to claim 5, wherein a condenser in which the cooling water is communicated is further provided on a pipeline of the steam outlet for communicating with the gas-liquid separator, and the condenser is configured to cool and liquefy the vaporized cooling liquid.

7. The cooling device according to claim 5, wherein the gas-liquid separator is further provided with a pressure regulating device for regulating an internal pressure of the gas-liquid separator.

8. The cooling device according to claim 7, wherein the pressure regulating device comprises a second one-way valve connected to the gas-liquid separator and a pressure regulator connected to the second one-way valve.

9. The cooling device according to claim 1, wherein the cooling liquid is selected from water, an organic solvent or a mixed liquid according to a working temperature of the heat generating object.

10. The cooling device according to claim 1, wherein a side wall of the tank is provided with an observation plate for observing an internal condition of the tank, and the observation plate is made of transparent quartz, acrylic or PC material.
